(19) United States
(12) Patent Application Publication
(10) Pub. No.: US 2026/0214791 A1
(43) Pub. Date: Jul. 23, 2026

(54) CIRCUIT BOARD STRUCTURE AND MANUFACTURING METHOD THEREOF

(71) Applicant: UNIMICRON TECHNOLOGY CORP., Taoyuan City (TW)

(72) Inventors: Yan-Ting LAI, Taoyuan City (TW); Kai-Wei WANG, Taoyuan City (TW); Wei-Yu LIAO, Taoyuan City (TW); Chun-Jui HUANG, Taoyuan City (TW); Ching-Sheng CHEN, Taoyuan City (TW)

(73) Assignee: UNIMICRON TECHNOLOGY CORP., Taoyuan City (TW)

(21) Appl. No.: 19/446,475

(22) Filed: Jan. 12, 2026

Related U.S. Application Data
(60) Provisional application No. 63/746,475, filed on Jan. 17, 2025.

(51) Int. Cl. H05K 1/02

(52) U.S. Cl. CPC H05K 1/0296

(57) ABSTRACT

A circuit board structure and a manufacturing method thereof are provided. The circuit board structure includes a substrate, a first circuit pattern, a second circuit pattern, and a dielectric layer. The first circuit pattern is disposed on the substrate, and the first circuit pattern has a first circuit density. The second circuit pattern is disposed on the substrate, and the second circuit pattern has a second circuit density, which is less than the first circuit density. The dielectric layer includes a first portion and a second portion. The first portion covers the first circuit pattern, wherein the first portion and the first circuit pattern together have a first thickness t1. The second portion covers the second circuit pattern, wherein the second portion and the second circuit pattern together have a second thickness t2, and |(t1−t2)|/(t1+t2)≤20%.

### CROSS REFERENCE TO RELATED APPLICATIONS

This application claims the benefit of U.S. provisional application No. 63/746,475, filed Jan. 17, 2025, the entirety of which is incorporated by reference herein.

### BACKGROUND OF THE INVENTION

### Field of the Invention

The present disclosure relates to circuit board structures, and, in particular, it relates to a circuit board structure with excellent uniformity of dielectric thickness, and a manufacturing method thereof.

### Description of the Related Art

As electronic devices are used more widely, user demands on their performance requirements are also increasing. To meet these demands, the designs of circuit board structures in electronic devices increasingly employ more complex circuit patterns than previous generations. However, these complex circuit patterns can result in uneven dielectric layer thickness, leading to the structural stability of the circuit board structure being insufficient. In other words, while existing circuit board structures and manufacturing methods thereof have gradually met their intended purposes, they do not meet requirements in all respects. Therefore, there is still a need for improvements to circuit board structures and the manufacturing methods thereof.

### BRIEF SUMMARY OF THE INVENTION

According to some embodiments, a circuit board structure is provided. The circuit board structure includes a substrate, a first circuit pattern, a second circuit pattern, and a dielectric layer. The first circuit pattern is disposed on the substrate. The first circuit pattern has a first circuit density. The second circuit pattern is disposed on the substrate. The second circuit pattern has a second circuit density, which is less than the first circuit density. The dielectric layer includes a first portion and a second portion. The first portion covers the first circuit pattern, wherein the first portion and the first circuit pattern together have a first thickness t1. The second portion covers the second circuit pattern, wherein the second portion and the second circuit pattern together have a second thickness t2, and |(t1−t2)|/(t1+t2)≤20%.

In some embodiments, |(t1−t2)|≤30 μm.

In some embodiments, the dielectric layer further includes a third portion in contact with the substrate. The third portion has a third thickness t3, and |(t1−t3)|/(t1+t3)≤20%.

In some embodiments, |(t1−t3)|≤30 μm.

In some embodiments, the first circuit density is greater than or equal to 80%.

In some embodiments, the first circuit pattern has a first circuit thickness, the second circuit pattern has a second circuit thickness, and the first circuit thickness is substantially the same as the second circuit thickness.

In some embodiments, the dielectric layer comprises one or more of prepreg, epoxy fiberglass board (FR-4), Ajinomoto build-up film (ABF), bismaleimide triazine (BT) resin, or a combination thereof.

According to some embodiments, a manufacturing method for a circuit board structure is provided. The manufacturing method includes: forming a first circuit pattern on a substrate, wherein the first circuit pattern has a first circuit density; forming a second circuit pattern on the substrate, wherein the second circuit pattern has a second circuit density, and the second circuit density is less than the first circuit density; forming at least one first opening on a dielectric film according to the first circuit density; and disposing a dielectric film having the at least one first opening on the first circuit pattern and the second circuit pattern to form a dielectric layer.

In some embodiments, the dielectric layer includes a first portion and a second portion. The first portion covers the first circuit pattern, wherein the first portion and the first circuit pattern together have a first thickness t1. The second portion covers the second circuit pattern, wherein the second portion and the second circuit pattern together have a second thickness t2, wherein |(t1−t2)|/(t1+t2)≤20%.

In some embodiments, |(t1−t2)|≤30 μm.

In some embodiments, the manufacturing method further includes: forming at least one second opening on the dielectric film according to the second circuit density; and disposing the dielectric film having the first opening and the second opening on the first circuit pattern and the second circuit pattern to form the dielectric layer.

In some embodiments, the dielectric layer further includes a third portion in contact with the substrate. The third portion has a third thickness t3, and |(t1−t3)|/(t1+t3)≤20%.

In some embodiments, |(t1−t3)|≤30 μm.

In some embodiments, the first circuit density is greater than or equal to 80%.

In some embodiments, the step of forming the first opening is performed by mechanical drilling, etch drilling, laser drilling, or a combination thereof.

In some embodiments, the first circuit pattern has a first volume, the first opening has a second volume, and the first volume is larger than the second volume.

In some embodiments, the second volume is at least 15% of the first volume.

In some embodiments, the manufacturing method further includes: forming a first positioning part on the substrate; forming a second positioning part on the dielectric film, wherein the second positioning part corresponds to the first positioning part; and attaching the dielectric film to the substrate according to the first positioning part and the second positioning part.

In some embodiments, the first circuit pattern has a first circuit thickness, the second circuit pattern has a second circuit thickness, and the first circuit thickness is substantially the same as the second circuit thickness.

In some embodiments, the dielectric layer comprises one or more of prepreg, epoxy fiberglass board (FR-4), Ajinomoto build-up film (ABF), bismaleimide triazine (BT) resin, or a combination thereof.

The circuit board structure and the manufacturing method thereof of the present disclosure may be applied in a variety of electric devices. In order to make the features and advantages of the present disclosure more comprehensible, various embodiments are specially cited hereinafter, together with the accompanying drawings, to be described in detail as follows.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1 to 3A are cross-sectional schematic views illustrating a circuit board structure at different stages in the manufacturing method according to some embodiments of the present disclosure;

FIG. 3B is a perspective schematic view illustrating a dielectric film according to some embodiments of the present disclosure;

FIGS. 4 to 6 are cross-sectional schematic views illustrating the circuit board structure at different stages in the manufacturing method according to some embodiments of the present disclosure; and

FIGS. 7 and 8 are cross-sectional schematic views illustrating the circuit board structure at different stages in the manufacturing method according to other embodiments of the present disclosure.

### DETAILED DESCRIPTION OF THE INVENTION

The devices of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simply and clearly describing some embodiments of the present disclosure, and does not imply any correlation between the different embodiments or structures discussed.

In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguish an element with a certain name and another element with the same name. The claims and the specification may not use the same terms, for example, a first element in the specification may be a second element in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to bonding and connection may also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” may still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

It should be understood that, in the following embodiments, features in several different embodiments may be replaced, recombined, and bonded to complete other embodiments without departing from the spirit of the present disclosure. The features of the various embodiments may be used in any combination as long as they do not violate the spirit of the present disclosure or conflict with each other.

Unless otherwise defined, all terms (including technical and scientific terms) used herein have the same meaning as commonly understood by a person of ordinary skill in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

In circuit board structures, multiple circuit patterns can be disposed on a substrate to achieve specific functions. The overlap area between these circuit patterns and the substrate (e.g., viewed in a projected manner) can be defined as circuit density or residual copper ratio (detailed calculations are described below). Different circuit patterns may have differences in circuit density (or residual copper ratio). As the number and complexity of circuit patterns increase, the differences in circuit density (or residual copper ratio) become more significant. This makes it difficult for the dielectric material disposed on the circuit pattern to form a blanket-covered structure. For example, in areas with high circuit density, the dielectric material is difficult to fill the gaps between lines by flow. On the other hand, in areas with low circuit density, the dielectric material may create a collapsed surface due to excessive filling of the gaps between lines. As a result, poor dielectric thickness uniformity may occur, which in turn affects subsequent processes or device stability.

To address at least some of the aforementioned problems, the present disclosure involves forming openings in the dielectric film corresponding to the circuit pattern before depositing the dielectric film on the circuit pattern. These openings facilitate the flow of the dielectric material. As a result, after depositing the dielectric film with openings on the circuit pattern, the distribution of the dielectric material can be effectively improved, thereby mitigating the problem of poor dielectric thickness uniformity. In other words, the present disclosure provides a circuit board structure with excellent dielectric thickness uniformity and a manufacturing method thereof.

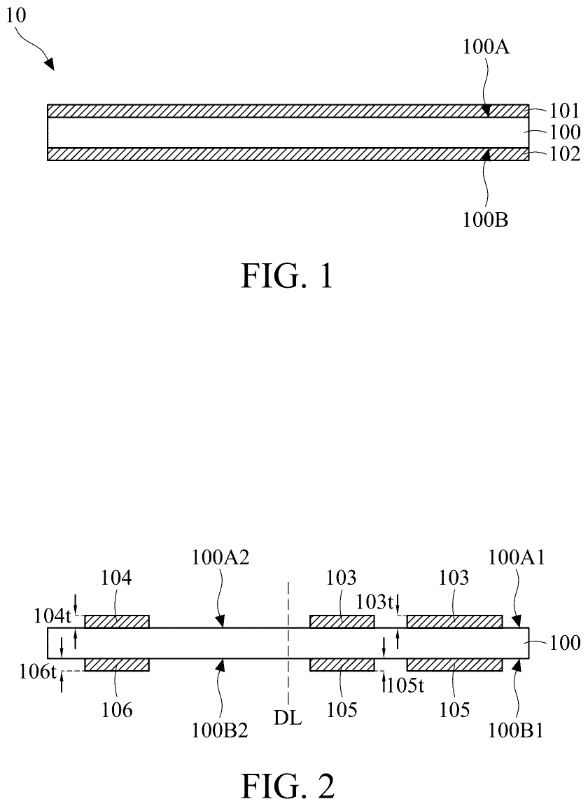

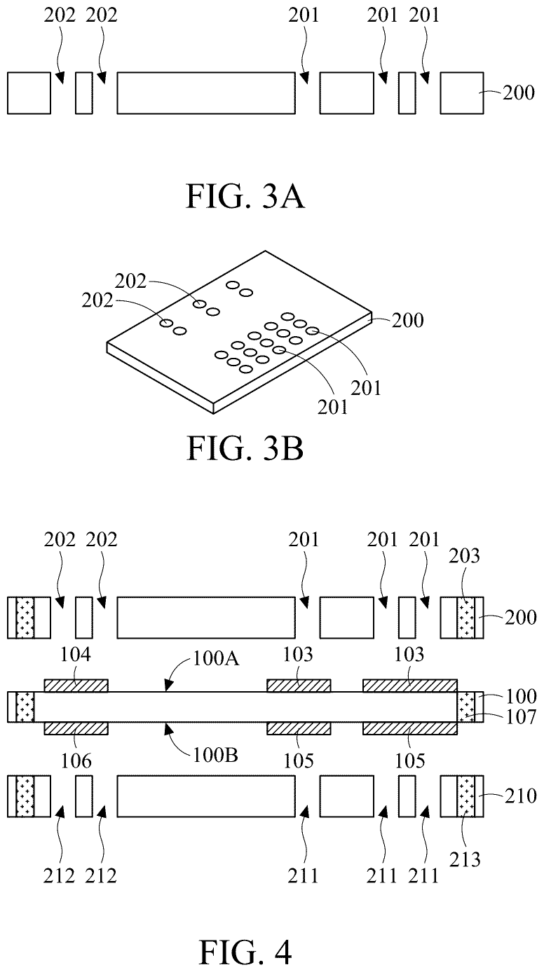

Referring to FIGS. 1 to 3A, 3B, and 4 to 6, wherein FIGS. 1 to 3A and 4 to 6 are cross-sectional schematic diagrams showing the circuit board structure in the manufacturing process at different stages according to some embodiments of the present disclosure, FIG. 3B is a perspective schematic diagram of the dielectric film. It should be noted that, for simplicity and ease of understanding, the figures in the present disclosure may exaggerate the dimensions of components and the proportions between them. Furthermore, the figures in the present disclosure may omit some components in the circuit board structure, but a person having ordinary skills in the art will understand that the circuit board structure may also include other common components, such as active components, passive components, pads, and redistribution layers (RDLs).

As shown in FIG. 1, the base substrate 10 is provided. The base substrate 10 may include the substrate 100, the conductor layer 101 and the conductor layer 102, wherein the conductor layer 101 and the conductor layer 102 are respectively disposed on the first surface 100A and the second surface 100B of the substrate 100.

In some embodiments, the substrate 100 may include polymeric materials, fibrous materials, prepreg, other suitable materials, or a combination thereof, but the present disclosure is not limited thereto. For example, polymeric materials may include epoxy resin, polyimide (PI), polypropylene (PP), other suitable polymeric materials, or a combination thereof, but the present disclosure is not limited thereto. For example, fibrous materials may include carbon fiber, glass fiber, other suitable fibrous materials, or a combination thereof, but the present disclosure is not limited thereto. In some embodiments, the conductor layer 101 and/or the conductor layer 102 may include aluminum (Al), copper (Cu), an alloy thereof, or a compound thereof, but the present disclosure is not limited thereto. For example, copper alloys or compounds may include brass, phosphor bronze, beryllium bronze, or oxygen-free copper, but the present disclosure is not limited thereto. In some embodiments, the base substrate 10 is a copper foil substrate.

As shown in FIG. 2, following the above steps, the conductor layer 101 is patterned to form a plurality of circuit patterns on the first surface 100A of the substrate 100. For example, the conductor layer 101 may be patterned as the first circuit pattern 103 and the second circuit pattern 104. In some embodiments, the plurality of circuit patterns located on the same side of the base substrate 10 may be separated from each other to perform different functions. For example, the first circuit pattern 103 and the second circuit pattern 104 on the first surface 100A of the substrate 100 may be used as an audio signal transmission line and an image signal transmission line, respectively, but the present disclosure is not limited thereto. Alternatively, these circuit patterns may also be different regions of a single circuit and together perform a specific function. For example, the first circuit pattern 103 and the second circuit pattern 104 on the first surface 100A of the substrate 100 may be used together as a power transmission line, but the present disclosure is not limited thereto.

In some embodiments, the first circuit pattern 103 has the first circuit thickness 103t, the second circuit pattern 104 has the second circuit thickness 104t, and the first circuit thickness 103t is substantially the same as the second circuit thickness 104t. However, the present disclosure is not limited thereto. In other embodiments, the first circuit thickness 103t may be different from the second circuit thickness 104t.

Following the steps described above, the conductor layer 102 is patterned to form a plurality of circuit patterns on the second surface 100B of the substrate 100. For example, the conductor layer 102 may be patterned as the third circuit pattern 105 and the fourth circuit pattern 106. Similarly, these circuit patterns may each perform different specific functions, or together perform a certain specific function.

In some embodiments, the third circuit pattern 105 has the third circuit thickness 105t, the fourth circuit pattern 106 has the fourth circuit thickness 106t, and the third circuit thickness 105t is substantially the same as the fourth circuit thickness 106t. However, the present disclosure is not limited thereto. In other embodiments, the third circuit thickness 105t may be different from the fourth circuit thickness 106t.

In some embodiments, circuit patterns may be formed only on one surface of the substrate 100 (e.g., the first surface 100A), and not on the other surface of the substrate 100 (e.g., the second surface 100B). In other words, the circuit board structure disclosed herein may be a single-sided circuit board structure, rather than necessarily a double-sided circuit board structure. In other embodiments, multi-layer circuit patterns may be formed on one surface of the substrate 100 (e.g., the first surface 100A), while a single-layer circuit pattern may be formed on the other surface of the substrate 100 (e.g., the second surface 100B). In other words, the circuit board structure disclosed herein may also be an asymmetrical double-sided circuit board structure. Therefore, the detailed process description of the circuit board structure in the present disclosure is merely an example. Without departing from the concept of the present disclosure, a person having ordinary skills in the art may arbitrarily modify the number of layers, configuration, and stacking pattern of the circuit board structure as needed.

In the present disclosure, when viewed from above (i.e., along the normal direction of substrate 100), the ratio of the projected area of the circuit pattern (i.e., the area of the circuit pattern itself overlapping the substrate) to the area of a selected region is called the circuit density or residual copper ratio. For example, when the projected area of the circuit pattern (i.e., the total area of the conductor viewed from above) is x, and the area of the selected region is y (where x≤y), the circuit density or residual copper ratio is defined as x/y (which may also be expressed as a percentage). The circuit density (or residual copper ratio) of this selected region will be used in subsequent processes to determine whether the corresponding part of the dielectric film needs to be processed (e.g., forming an opening). In some embodiments, the smallest area of a rectangle, circle, or other suitable shape that may cover the entire circuit pattern may be used as the selected region to determine the circuit density (or residual copper ratio) under this condition. However, the present disclosure is not limited thereto. In other embodiments, any suitable region may be arbitrarily selected as the selected region to determine the circuit density (or residual copper ratio) under this condition. In some embodiments, when there is no circuit pattern in the selected area, the circuit density (or residual copper ratio) of this area may be defined to be substantially 0%. Conversely, when the selected area is completely covered by a circuit pattern, the circuit density (or residual copper ratio) of this area may be defined to be substantially 100%.

As described above, the first circuit pattern 103 and the second circuit pattern 104 may have different circuit densities. For example, the first circuit pattern 103 may have a first circuit density (i.e., the ratio of the total top view area of the first circuit pattern 103 to the area 100A1), and the second circuit pattern 104 may have a second circuit density (i.e., the ratio of the total top view area of the second circuit pattern 104 to the area 100A2), wherein the second circuit density is less than the first circuit density. In other words, the first circuit pattern 103 is denser than the second circuit pattern 104 per unit area. For ease of understanding, FIG. 2 divides the substrate 100 into an upper right half (with the area 100A1) and an upper left half (with the area 100A2) of the same size by a dashed line DL, such that the area 100A1 is substantially the same as the area 100A2. However, as mentioned above, in other embodiments, the position of the dashed line DL may be arbitrarily chosen as needed, or the areas 100A1 and 100A2 may be arbitrarily defined to be different from each other.

Similarly, the third circuit pattern 105 and the fourth circuit pattern 106 may have different circuit densities. For example, the third circuit pattern 105 may have a third circuit density (i.e., the ratio of the total top view area of the third circuit pattern 105 to area 100B1), and the fourth circuit pattern 106 may have a fourth circuit density (i.e., the ratio of the total top view area of the fourth circuit pattern 106 to area 100B2), wherein the fourth circuit density is less than the third circuit density. In other words, the third circuit pattern 105 is denser than the fourth circuit pattern 106 per unit area. For ease of understanding, FIG. 2 divides the substrate 100 into a lower right half (with the area 100B1) and a lower left half (with the area 100B 2) of the same size by a dashed line DL, such that area 100B1 is substantially the same as area 100B2. However, as mentioned above, in other embodiments, the position of the dashed line DL may be arbitrarily chosen as needed, or the areas 100B1 and 100B2 may be arbitrarily defined to be different from each other.

In some embodiments, the conductor layer 101 and/or the conductor layer 102 may be patterned by a combination of photolithography and etching processes. In some embodiments, the photolithography process may include photoresist application (e.g., spin-on coating, lamination), soft baking, mask alignment, exposure, post-exposure baking, photoresist developing, rinsing, drying (e.g., spin-drying and/or hard baking), other suitable photolithography techniques, and/or a combination thereof, but the present disclosure is not limited thereto. In some embodiments, the etching process may include dry etching, wet etching, other suitable etching, or a combination thereof, but the present disclosure is not limited thereto.

As shown in FIGS. 3A and 3B, following the steps described above, the dielectric film 200 is provided, and openings (e.g., the openings 201 and 202) are formed on the dielectric film 200. These openings are used to adjust the flowability of the dielectric film 200 in subsequent processes. Specifically, a higher circuit density indicates a higher coverage of the circuit pattern per unit area, meaning smaller gaps between adjacent lines. In this case, even if the dielectric film 200 is attached to the circuit pattern and softened or melted by applying heat or pressure, it is still difficult for the softened or melted dielectric film 200 to flow and fill the gaps between adjacent lines. As a result, the stack that is formed will have a noticeable uneven surface, such as a conformal surface caused by the protrusion of the circuit pattern (e.g., a top surface with an uneven shape). These uneven surfaces are detrimental to the planarization of the circuit board structure. To solve this problem, the present disclosure improves the flowability of the dielectric film 200 by removing a portion of it. Specific methods and related parameters are described below.

In some embodiments, the location of the opening may be determined based on the circuit density. For example, when the circuit density of a selected area is greater than or equal to 50%, an opening corresponding to that area may be formed on the dielectric film 200. Conversely, when the circuit density of another selected area is less than 50%, an opening corresponding to that area may not be formed on the dielectric film 200. Of course, the above values are merely examples, and the present disclosure is not limited thereto. A person having ordinary skills in the art may determine the threshold of the circuit density corresponding to the formation of the opening based on the material of the dielectric film 200, the applied temperature, the applied pressure, the applied time, or other conditions. For example, “circuit density greater than or equal to 80%” may be defined as the threshold, and a local area of the dielectric film corresponding to it may be processed (forming an opening).

In other embodiments, the size of the openings (corresponding to the volume of the removed dielectric film) may be determined based on the volume of the circuit pattern. For example, one or more openings with volumes corresponding to the circuit pattern may be formed on the dielectric film 200, and the total volume of these openings may be approximately 50% of the volume of the circuit pattern. Of course, the above values are merely examples, and the present disclosure is not limited thereto. A person having ordinary skills in the art may determine the total volume and number of openings formed based on the type of material of the dielectric film 200, the applied temperature, the applied pressure, the application time, or other conditions.

In some embodiments, the volume of the circuit pattern depends on both the thickness of the circuit pattern (e.g., the first circuit thickness of 103t to the fourth circuit thickness of 106t) and the circuit density (e.g., the first circuit density to the fourth circuit density). In some embodiments, the thickness and circuit density of the circuit pattern have different degrees of influence on the size of the opening. For example, the circuit density (related to the gap between adjacent lines) may have a more significant impact on the fluidity of the dielectric film than the circuit thickness of the circuit pattern. Therefore, a person having ordinary skills in the art may adjust the volume of the opening according to the actual situation.

In some embodiments, the top view shape of the opening may be triangular, circular, elliptical, rectangular, polygonal, or other suitable shapes. In some embodiments, the side view shape of the opening may be vertical, dumbbell-shaped, funnel-shaped, or other suitable shapes. In some embodiments, the arrangement of the openings may be determined according to the flow requirements reflected by the circuit density. For example, multiple openings having volumes corresponding to the circuit pattern may be formed on the dielectric film 200, and these openings may be arranged in a matrix, a specific pattern, or arbitrarily on the dielectric film 200. In some embodiments, one or more openings may penetrate the dielectric film 200 or not, depending on the ease of processing, the characteristics of the dielectric film 200, or other means. In some embodiments, when there are multiple openings, these openings may be the same or different from each other. “The same or different” here may refer to shape, size, arrangement, whether it penetrates the dielectric film 200, etc.

Referring back to FIGS. 3A and 3B; the corresponding first opening 201 may be formed on the dielectric film 200 according to the first circuit density of the first circuit pattern 103, and the corresponding second opening 202 may optionally be formed on the dielectric film 200 according to the second circuit density of the second circuit pattern 104. In some embodiments, the first circuit density is greater than or equal to 80%, while the second circuit density is less than 80%. In this case, the size of a single first opening 201 may be the same as the size of a single second opening 202, while the number of first openings 201 may be greater than the number of second openings 202. Alternatively, the number of first openings 201 may be the same as the number of second openings 202, while the size of a single first opening 201 may be greater than the size of a single second opening 202. This configuration allows local areas of the dielectric film 200 to have flowability matching the first circuit pattern 103 and the second circuit pattern 104 in subsequent processes.

In some embodiments, the first circuit pattern 103 has a first volume, and the first opening 201 has a second volume (if there are multiple first openings 201, the second volume is the total volume of the multiple first openings 201), and the first volume is larger than the second volume. For example, the second volume is at least 15% but less than 80% of the first volume. When the second volume is too small (e.g., less than 15%), the first opening 201 may not provide (or improve) sufficient flowability for the dielectric film 200. However, when the second volume is too large (e.g., greater than or equal to 80%), it may cause porosity in the subsequently formed dielectric layer, or even result in insufficient total volume of the dielectric layer, leading to surface depressions. Similarly, these configurations may be applied to the relationship between the second circuit pattern 104 and the second opening 202. In some embodiments, the second volume is approximately 20% of the first volume.

In some embodiments, another dielectric film (e.g., the dielectric film 210 of FIG. 4) may be provided, and at least one third opening (e.g., the third opening 211 of FIG. 4) corresponding to the third circuit pattern 105 and at least one fourth opening (e.g., the fourth opening 212 of FIG. 4) corresponding to the fourth circuit pattern 106 may be formed as described above. Similarly, the above configuration may be applied to the relationship between the third circuit pattern 105 and the third opening, and to the relationship between the fourth circuit pattern 106 and the fourth opening.

In some embodiments, the dielectric film 200 and/or the dielectric film 210 may include prepreg, epoxy fiberglass board (FR-4), Ajinomoto build-up film (ABF), bismaleimide triazine (BT) resin, other suitable materials, or a combination thereof, but the present disclosure is not limited thereto. In some embodiments, the dielectric film 200 and/or the dielectric film 210 may include a single-layer structure or a multilayer structure. In embodiments where the dielectric film 200 (or the dielectric film 210) includes a multilayer structure, any parameters of the thickness, material, and shape of the multiple layers may be the same or different from each other.

In some embodiments, the steps of forming the first opening 201, the second opening 202, the third opening 211, and/or the fourth opening 212 may employ one or more of mechanical drilling, etch drilling, laser drilling, another suitable drilling process, or a combination thereof. For example, a suitable drilling process may be selected based on conditions such as the type of the dielectric film 200 or the dielectric film 210, the shape (or size) of the opening, etc.

As shown in FIG. 4, following the above steps, the dielectric film 200 and/or the dielectric film 210 are aligned with the substrate 100. In some embodiments, the above alignment process may be implemented by positioning parts. For example, the alignment process includes: forming the first positioning part 107 on the substrate 100; forming the second positioning part 203 on the dielectric film 200, wherein the second positioning part corresponds to the first positioning part 107; attaching the dielectric film 200 to the substrate 100 by means of the first positioning part 107 and the second positioning part 203; forming the third positioning part 213 on the dielectric film 210, wherein the third positioning part 213 corresponds to the first positioning part 107; and attaching the dielectric film 210 to the substrate 100 by means of the first positioning part 107 and the third positioning part 213.

The first positioning part 107 may include a protruding structure, such as an alignment pin, positioning pin, alignment post, or other suitable structure. Correspondingly, the second positioning part 203 and/or the third positioning part 213 may include a recessed structure, such as an alignment hole, through hole, blind hole, groove, notch, or other suitable structure. However, the present disclosure is not limited thereto. In other embodiments, the first positioning part 107 may include a recessed structure, while the second positioning part 203 and/or the third positioning part 213 may include a corresponding protruding structure.

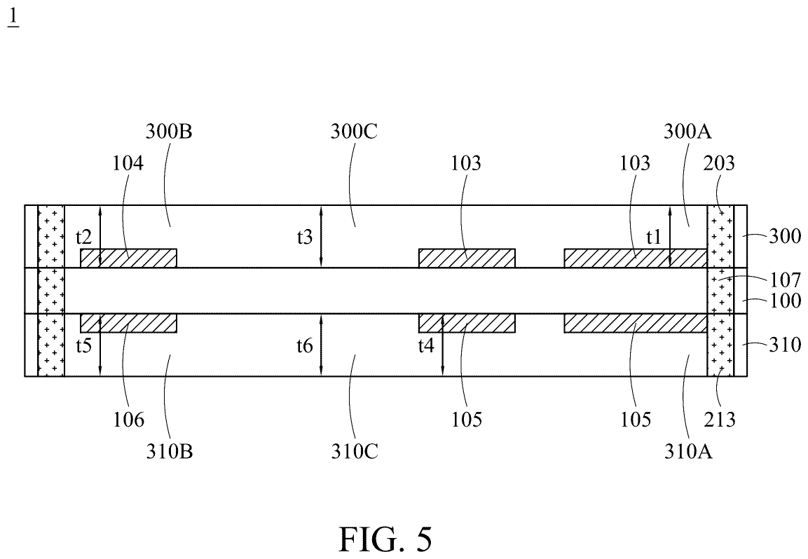

As shown in FIG. 5, following the above steps, the dielectric film 200 having the first openings 201 and the second openings 202 is disposed on the first circuit pattern 103 and the second circuit pattern 104 to form the dielectric layer 300. In some embodiments, the dielectric film 200 may be softened or melted by applying heat or pressure to form the dielectric layer 300 with a blanket structure on the substrate 100.

In some embodiments, the dielectric layer 300 may be divided into multiple portions according to its location. For example, the dielectric layer 300 may include the first portion 300A and the second portion 300B. The first portion 300A covers the first circuit pattern 103, and the first portion 300A and the first circuit pattern 103 together have the first thickness t1. The second portion 300B covers the second circuit pattern 104, and the second portion 300B and the second circuit pattern 104 together have the second thickness t2. In some embodiments, |(t1−t2)|≤30 μm. For example, the difference between the first thickness t1 and the second thickness t2 may be 30 μm, 25 μm, 20 μm, 15 μm, 10 μm, 5 μm, 0 μm, or any value or range between the above values. In some embodiments, |(t1−t2)|/(t1+t2) may be defined as the degree of thickness variation between the first portion 300A and the second portion 300B on the substrate 100, and |(t1−t2)|/(t1+t2)≤20%. For example, the degree of thickness variation may be 20%, 15%, 10%, 5%, 0%, or any value or range between the above values. As expressed by the formula, the smaller the difference between the first thickness t1 and the second thickness t2, the higher the flatness of the high-density wiring area and the low-density wiring area.

In some embodiments, the dielectric layer 300 further includes the third portion 300C. The third portion 300C is in contact with the substrate 100, wherein the third portion 300C has the third thickness t3. Specifically, there is no circuit pattern between the third portion 300C and the substrate 100, that is, the third thickness t3 is the thickness of the dielectric layer 300 itself. In some embodiments, |(t1−t3)|≤30 μm. For example, the difference between the first thickness t1 and the third thickness t3 may be 30 μm, 25 μm, 20 μm, 15 μm, 10 μm, 5 μm, 0 μm, or any value or range between the above values. In some embodiments, |(t1−t3)|/(t1+t3) may be defined as the degree of thickness variation between the first portion 300A and the third portion 300C on the substrate 100, and |(t1−t3)|/(t1+t3)≤20%. For example, the degree of thickness variation may be 20%, 15%, 10%, 5%, 0%, or any value or range between these. As expressed by the formula, the smaller the difference between the first thickness t1 and the third thickness t3, the higher the flatness of the wiring area and the non-wiring area.

Following the above steps, the dielectric film 210 having the third openings 211 and the fourth openings 212 is disposed on the third circuit pattern 105 and the fourth circuit pattern 106 to form the dielectric layer 310. In some embodiments, the dielectric film 210 may be softened or melted by applying heat or pressure to form a dielectric layer 310 with a blanket structure on the substrate 100.

In some embodiments, the dielectric layer 310 may be divided into multiple portions according to its location. For example, the dielectric layer 310 may include the fourth portion 310A and the fifth portion 310B. The fourth portion 310A covers the third circuit pattern 105, and the fourth portion 310A and the third circuit pattern 105 together have the fourth thickness t4. The fifth portion 310B covers the fourth circuit pattern 106, and the fifth portion 310B and the fourth circuit pattern 106 together have the fifth thickness t5. In some embodiments, |(t4−t5)|≤30 μm. For example, the difference between the fourth thickness t4 and the fifth thickness t5 may be 30 μm, 25 μm, 20 μm, 15 μm, 10 μm, 5 μm, 0 μm, or any value or range between the above values. In some embodiments, |(t4−t5)|/(t4+t5) may be defined as the degree of thickness variation between the fourth portion 310A and the fifth portion 310B on the substrate 100, and |(t4−t5)|/(t4+t5)≤20%. For example, the degree of thickness variation may be 20%, 15%, 10%, 5%, 0%, or any value or range between the above values.

In some embodiments, the dielectric layer 310 may further include the sixth portion 310C. The sixth portion 310C contacts the substrate 100, wherein the sixth portion 310C has the sixth thickness t6. Specifically, there is no circuit pattern between the sixth portion 310C and the substrate 100, that is, the sixth portion 310C is the thickness of the dielectric layer 310 itself. In some embodiments, |(t4−t6)|≤30 μm. For example, the difference between the fourth thickness t4 and the sixth thickness t6 may be 30 μm, 25 μm, 20 μm, 15 μm, 10 μm, 5 μm, 0 μm, or any value or range between the above values. In some embodiments, |(t4−t6)|/(t4+t6) may be defined as the degree of thickness variation between the fourth portion 310A and the sixth portion 310C on the substrate 100, and |(t4−t6)|/(t4+t6)≤20%. For example, the degree of thickness variation may be 20%, 15%, 10%, 5%, 0%, or any value or range between the above values.

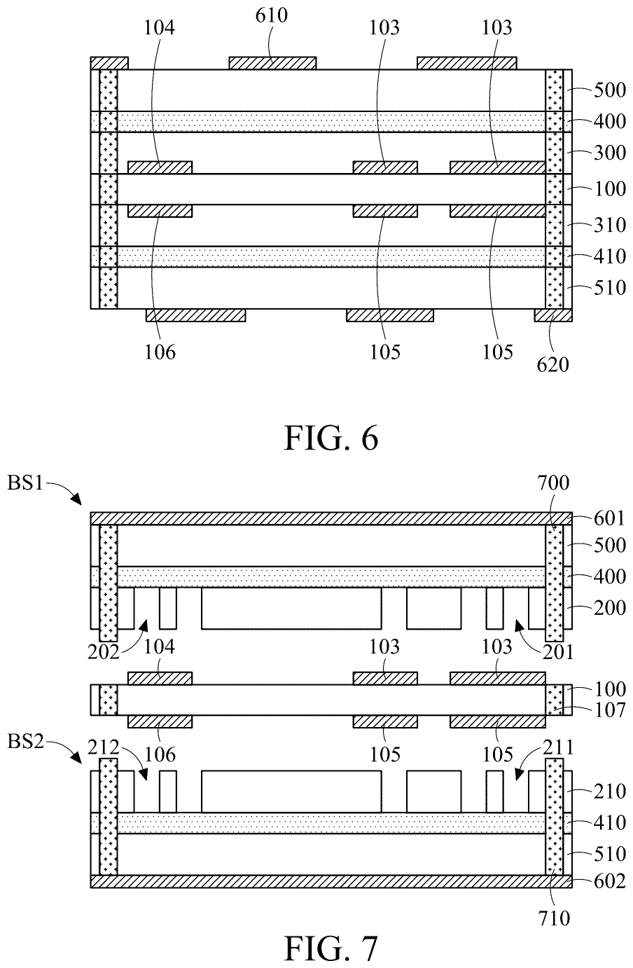

Through the above-described process, the circuit board structure 1 with a flat top surface (outermost surface) may be obtained. In some embodiments, the circuit board structure 1 may be further subjected to a lamination process to form a more complex and multi-layered circuit board structure. For example, as shown in FIG. 6, following the above steps, the adhesive layer 400, the dielectric layer 500, and the circuit pattern 610 may be sequentially disposed on the dielectric layer 300, and the adhesive layer 410, the dielectric layer 510, and the circuit pattern 620 may be sequentially disposed on the dielectric layer 310. In some embodiments, the adhesive layer 400 and/or the adhesive layer 410 may include a prepreg, a thermosetting resin, a photocurable resin, other suitable materials, or a combination thereof, but the present disclosure is not limited thereto. In some embodiments, the dielectric layer 500 and/or the dielectric layer 510 may include epoxy resin, polyimide (PI), an additive layer material (ABF), other suitable dielectric materials, or a combination thereof, but the present disclosure is not limited thereto. In some embodiments, circuit pattern 610 and/or circuit pattern 620 may include aluminum (Al), copper (Cu), alloys thereof, or compounds thereof, but the present disclosure is not limited thereto.

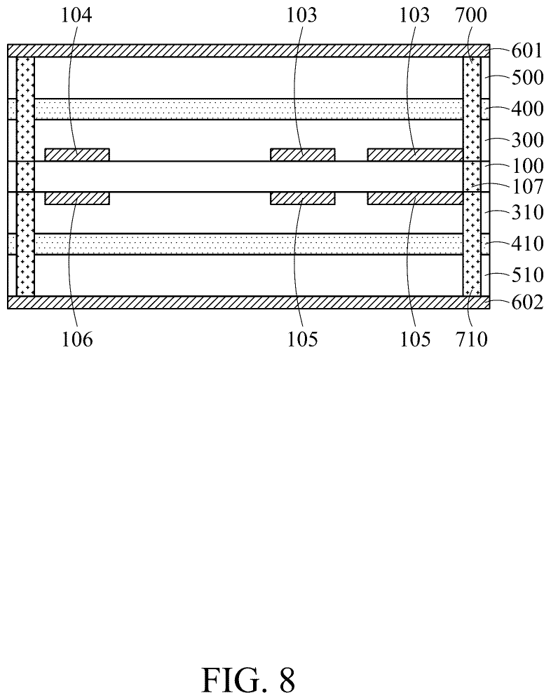

Referring to FIGS. 7 and 8, FIGS. 7 and 8 are cross-sectional schematic diagrams showing the circuit board structure at different stages in the manufacturing method according to some other embodiments of the present disclosure. In these embodiments, the steps of FIGS. 1 to 2 are followed, and the steps of FIG. 7 are used instead of the steps of FIGS. 3A, 4, and 5, thereby simplifying the manufacturing process of the circuit board structure. Specifically, unlike the above-described method of separately disposing dielectric films (e.g., the dielectric film 200, the dielectric film 210), adhesive layers (e.g., the adhesive layer 400, the adhesive layer 410), dielectric layers (e.g., the dielectric layer 500, the dielectric layer 510), and circuit patterns (e.g., the circuit pattern 610, the circuit pattern 620) on the substrate 100, this embodiment first combines the above-described components to form a build-up stack (e.g., the build-up stack BS1, the build-up stack BS2), and then disposes the build-up stack on the substrate 100, thereby improving process flexibility for different products.

As shown in FIG. 7, in some embodiments, the build-up stack BS1 is provided, which includes the dielectric film 200, the adhesive layer 400, the dielectric layer 500, and the conductor layer 601 stacked sequentially. The dielectric film 200 has at least one first opening 201 and at least one second opening 202. Following the above steps, another build-up stack BS2 is provided, which includes the dielectric film 210, the adhesive layer 410, the dielectric layer 510, and the conductor layer 602 stacked sequentially. The dielectric film 210 has at least one third opening 211 and at least one fourth opening 212. Following the above steps, the build-up stacks BS1 and BS2 are aligned with the substrate 100. In some embodiments, the alignment process may be implemented by positioning parts such as the fourth positioning part 700 and the fifth positioning part 710. The specific configuration and function of the above elements may be referred to above and will not be repeated here.

As shown in FIG. 8, the build-up stacks BS1 and BS2 are disposed on substrate 100. Further, the dielectric film 200 blanket-covers the first circuit pattern 103 and the second circuit pattern 104 by applying heat or pressure, and the dielectric film 210 blanket-covers the third circuit pattern 105 and the fourth circuit pattern 106 by applying heat or pressure. Because the first openings 201 and the second openings 202 on dielectric film 200 provide sufficient space, the softened or melted dielectric film 200 may effectively penetrate into the gaps between adjacent lines of the first circuit pattern 103 and the second circuit pattern 104. Similarly, because the third openings 211 and the fourth openings 212 on dielectric film 210 provide sufficient space, the softened or melted dielectric film 210 may effectively penetrate into the gaps between adjacent lines of the third circuit pattern 105 and the fourth circuit pattern 106. Following the above steps, the conductor layer 601 is patterned to form the circuit pattern 610, and the conductor layer 602 is patterned to form the circuit pattern 620, thereby obtaining the structure of FIG. 6.

In summary, the present disclosure involves forming openings in the dielectric film corresponding to the circuit pattern before depositing the dielectric film on the circuit pattern. These openings facilitate the flow of the dielectric material. As a result, after depositing the dielectric film with openings on the circuit pattern, the distribution of the dielectric material can be effectively improved, thereby mitigating the problem of poor dielectric thickness uniformity. In other words, the present disclosure provides a circuit board structure with excellent dielectric thickness uniformity and a manufacturing method thereof.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit board structure, comprising:
a substrate;
a first circuit pattern disposed on the substrate, wherein the first circuit pattern has a first circuit density;
a second circuit pattern disposed on the substrate, wherein the second circuit pattern has a second circuit density, and the second circuit density is less than the first circuit density; and
a dielectric layer, comprising:
a first portion covering the first circuit pattern, wherein the first portion and the first circuit pattern together have a first thickness t1; and
a second portion covering the second circuit pattern, wherein the second portion and the second circuit pattern together have a second thickness t2,
wherein |(t1−t2)|/(t1+t2)≤20%.

2. The circuit board structure as claimed in claim 1, wherein

|(t1−t2)|≤30 μm.

3. The circuit board structure as claimed in claim 1, wherein
the dielectric layer further comprises:
a third portion in contact with the substrate, wherein the third portion has a third thickness t3,
wherein |(t1−t3)|/(t1+t3)≤20%.

4. The circuit board structure as claimed in claim 3, wherein

|(t1−t3)|≤30 μm.

5. The circuit board structure as claimed in claim 1, wherein the first circuit density is greater than or equal to 80%.

6. The circuit board structure as claimed in claim 1, wherein the first circuit pattern has a first circuit thickness, the second circuit pattern has a second circuit thickness, and the first circuit thickness is substantially the same as the second circuit thickness.

7. The circuit board structure as claimed in claim 1, wherein the dielectric layer comprises one or more of prepreg, epoxy fiberglass board (FR-4), Ajinomoto build-up film (ABF), and bismaleimide triazine (BT) resin.

8. A manufacturing method for a circuit board structure, comprising:
forming a first circuit pattern on a substrate, wherein the first circuit pattern has a first circuit density;
forming a second circuit pattern on the substrate, wherein the second circuit pattern has a second circuit density, and the second circuit density is less than the first circuit density;
forming at least one first opening on a dielectric film according to the first circuit density; and
disposing a dielectric film having the at least one first opening on the first circuit pattern and the second circuit pattern to form a dielectric layer.

9. The manufacturing method for the circuit board structure as claimed in claim 8, wherein the dielectric layer comprises:
a first portion covering the first circuit pattern, wherein the first portion and the first circuit pattern together have a first thickness t1; and
a second portion covering the second circuit pattern, wherein the second portion and the second circuit pattern together have a second thickness t2,
wherein |(t1−t2)|/(t1+t2)≤20%.

10. A manufacturing method for a circuit board structure as claimed in claim 9, wherein

|(t1−t2)|≤30 μm.

11. The manufacturing method for the circuit board structure as claimed in claim 8 further comprises:
forming at least one second opening on the dielectric film according to the second circuit density; and
disposing the dielectric film having the at least one first opening and the at least one second opening on the first circuit pattern and the second circuit pattern to form the dielectric layer.

12. The manufacturing method for the circuit board structure as claimed in claim 11, wherein
the dielectric layer further comprises:
a third portion in contact with the substrate, wherein the third portion has a third thickness t3,
wherein |(t1−t3)|/(t1+t3)≤20%.

13. The manufacturing method for the circuit board structure as claimed in claim 12, wherein

|(t1−t3)|≤30 μm.

14. The manufacturing method for the circuit board structure as claimed in claim 8, wherein the first circuit density is greater than or equal to 80%.

15. The manufacturing method for the circuit board structure as claimed in claim 8, wherein the step of forming the at least one first opening is performed by one or more of mechanical drilling, etch drilling, and laser drilling.

16. The manufacturing method for the circuit board structure as claimed in claim 8, wherein the first circuit pattern has a first volume, the at least one first opening has a second volume, and the first volume is larger than the second volume.

17. The manufacturing method for the circuit board structure as claimed in claim 16, wherein the second volume is at least 15% of the first volume.

18. The manufacturing method for the circuit board structure as claimed in claim 8 further comprises:
forming a first positioning part on the substrate;
forming a second positioning part on the dielectric film, wherein the second positioning part corresponds to the first positioning part; and
attaching the dielectric film to the substrate according to the first positioning part and the second positioning part.

19. The manufacturing method for the circuit board structure as claimed in claim 8, wherein the first circuit pattern has a first circuit thickness, the second circuit pattern has a second circuit thickness, and the first circuit thickness is substantially the same as the second circuit thickness.

20. The manufacturing method for the circuit board structure as claimed in claim 8, wherein the dielectric layer comprises one or more of prepreg, epoxy fiberglass board, Ajinomoto build-up film (ABF), and bismaleimide triazine (BT) resin.
